(19) United States
(12) Patent Application Publication
(10) Pub. No.: US 2021/0208689 A1
(43) Pub. Date: Jul. 8, 2021

(54) PROXIMITY DETECTION METHOD AND PROXIMITY DETECTION KEYBOARD

(71) Applicant: Integrated Silicon Solution Inc., Milpitas, CA (US)

(72) Inventors: Huai-Tsu CHANG, Milpitas, CA (US); Ku-Hsiung FENG, Milpitas, CA (US); Chia-Hsien CHANG, Milpitas, CA (US); Wen-Hsiang LIN, Milpitas, CA (US)

(21) Appl. No.: 17/088,651

(22) Filed: Nov. 4, 2020

Related U.S. Application Data
(60) Provisional application No. 62/957,364, filed on Jan. 6, 2020.

(51) Int. Cl. G06F 3/02; G06F 3/044; G06F 3/0488

(52) U.S. Cl. CPC G06F 3/021; G06F 2203/04101; G06F 3/04883; G06F 3/044

(57) ABSTRACT

A proximity detection method is for detecting if a user is proximate to a proximity detection keyboard, and the proximity detection keyboard includes a plurality of electrodes and at least one grounding element, which is disposed correspondingly to the electrodes. The proximity detection method includes an equivalent capacitance detecting step and a proximity event determining step. The equivalent capacitance detecting step is for detecting an equivalent capacitance of each of the electrodes. The equivalent capacitance of each of the electrodes is defined by a corresponding proximity capacitance and a corresponding parasitic capacitance. A proximity event determining step is for comparing the equivalent capacitance of at least one of the electrodes and a corresponding capacitance threshold value to determine if a proximity event is existed. The electrodes are respectively corresponding to the capacitance threshold values being predetermined.

### RELATED APPLICATIONS

The application claims priority to U.S. Provisional Application Ser. No. 62/957,364, filed Jan. 6, 2020, which is herein incorporated by reference.

### BACKGROUND

### Technical Field

The present disclosure relates to a proximity detection method and a proximity detection keyboard. More particularly, the present disclosure relates to a proximity detection method and a proximity detection keyboard applying a capacitance of an electrode.

### Description of Related Art

Recently, with the development of the information technology and the prosperity of the entertainment industry, the requirements for the functions and specifications of keyboards or keypads are also increasing. The conventional standard keyboards and gaming keyboards in the market are often difficult to be favored by consumers due to the lack of attractive features.

Given the above, in the market, it is urgent to develop a keyboard with attractive functions, such as a proximity detection keyboard, which provides users with proximity pre-detections when their palms, fingers, and wrists are approaching. Thus, the strict demands of keyboards from the users could be satisfied, while having the benefits of saving the development cost and time.

### SUMMARY

According to one aspect of the present disclosure, a proximity detection method is for detecting if a user is proximate to a proximity detection keyboard, and the proximity detection keyboard includes a plurality of electrodes and at least one grounding element, which is disposed correspondingly to the electrodes. The proximity detection method includes an equivalent capacitance detecting step and a proximity event determining step. The equivalent capacitance detecting step is for detecting an equivalent capacitance of each of the electrodes. A proximity capacitance is generated between each of the electrodes and the user. A parasitic capacitance is generated between each of the electrodes and the corresponding grounding element. The equivalent capacitance of each of the electrodes is defined by the corresponding proximity capacitance and the corresponding parasitic capacitance. The proximity event determining step is for comparing the equivalent capacitance of at least one of the electrodes and a corresponding capacitance threshold value to determine if a proximity event is existed. The electrodes are respectively corresponding to the capacitance threshold values being predetermined.

According to another aspect of the present disclosure, a proximity detection keyboard includes a plurality of buttons, a clearance housing portion, a plurality of electrodes, at least one grounding element, a processer and a nonvolatile memory. The clearance housing portion is made of non-electrically-conductive material. Any of the buttons is not disposed on the clearance housing portion. The electrodes are correspondingly disposed inside the clearance housing portion. The at least one grounding element is disposed correspondingly to the electrodes. The processer is coupled to the buttons, the electrodes and the at least one grounding element. The nonvolatile memory is coupled to the processer and configured to provide a proximity detection module. The processer is configured to determine if a proximity event is existed according to the proximity detection module, and the proximity detection module is for performing an equivalent capacitance detecting step and a proximity event determining step. The equivalent capacitance detecting step is detecting an equivalent capacitance of each of the electrodes. A proximity capacitance is generated between each of the electrodes and a user. A parasitic capacitance is generated between each of the electrodes and the corresponding grounding element. The equivalent capacitance of each of the electrodes is defined by the corresponding proximity capacitance and the corresponding parasitic capacitance. The proximity event determining step is comparing the equivalent capacitance of at least one of the electrodes and a corresponding capacitance threshold value to determine if the proximity event is existed, and the electrodes are respectively corresponding to the capacitance threshold values being predetermined.

### BRIEF DESCRIPTION OF THE DRAWINGS

The present disclosure can be more fully understood by reading the following detailed description of the embodiment, with reference made to the accompanying drawings as follows:

FIG. 1 is a flow chart of a proximity detection method according to the 1st embodiment of the present disclosure.

FIG. 2 is a flow chart of a proximity detection method according to the 2nd embodiment of the present disclosure.

FIG. 3A is a block diagram of a proximity detection keyboard according to the 3rd embodiment of the present disclosure.

FIG. 3B is a schematic view of the proximity detection keyboard according to the 3rd embodiment.

FIG. 3C is a schematic view of the proximity detection keyboard according to the 3rd embodiment and a user.

FIG. 3D is a schematic view of a proximity capacitance and a parasitic capacitance of one of electrodes according to the 3rd embodiment.

### DETAILED DESCRIPTION

The embodiment will be described with the drawings. For clarity, some practical details will be described below. However, it should be noted that the present disclosure should not be limited by the practical details, that is, in some embodiments, the practical details is unnecessary. In addition, for simplifying the drawings, some conventional structures and elements will be simply illustrated, and repeated elements may be represented by the same labels.

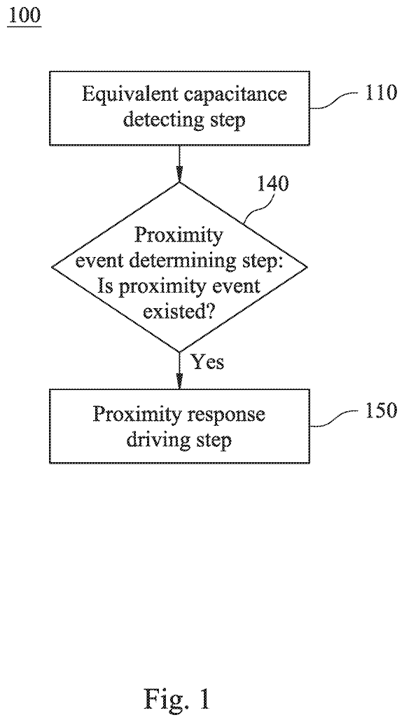

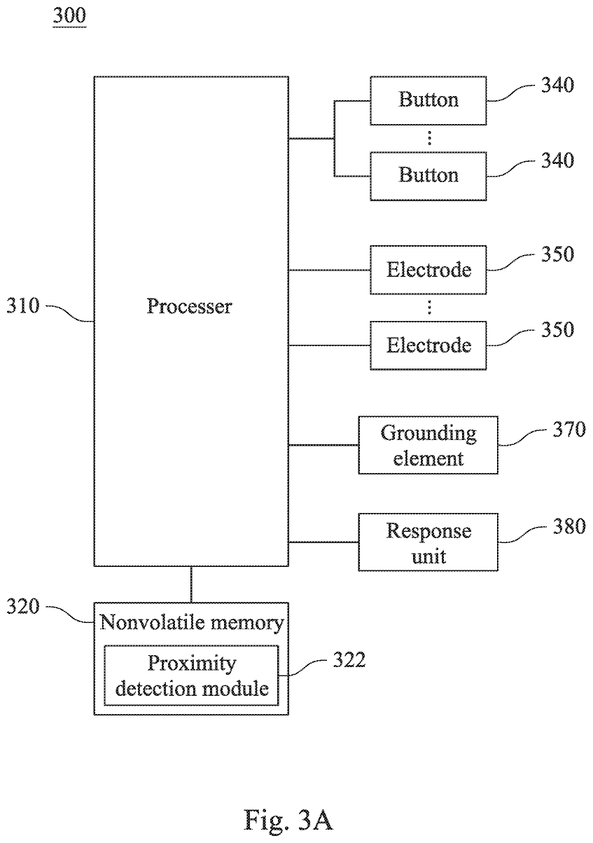

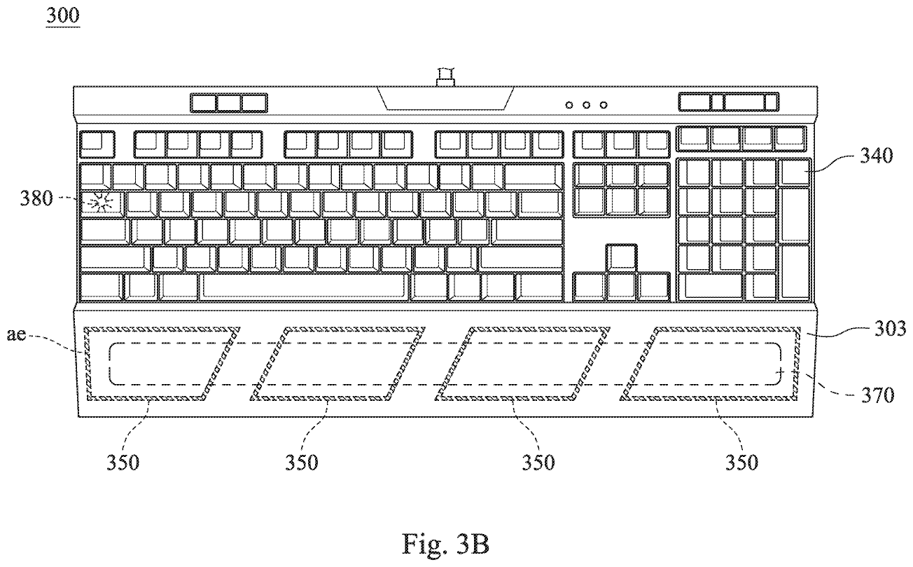

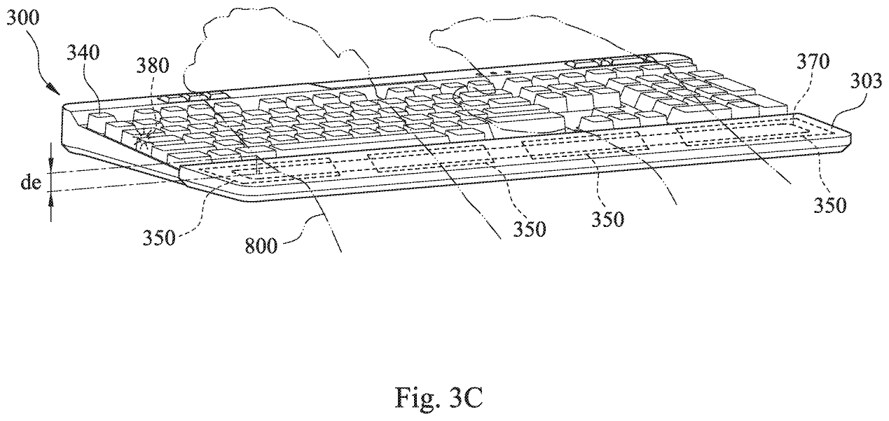

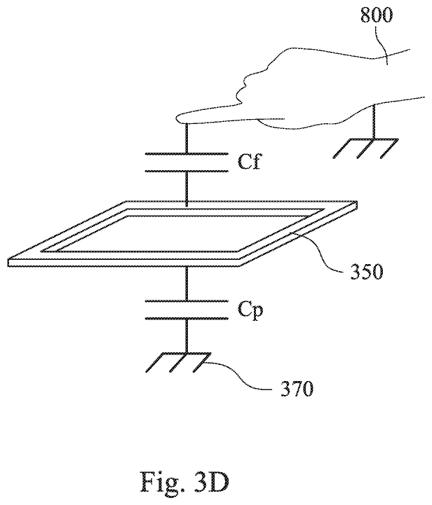

FIG. 1 is a flow chart of a proximity detection method 100 according to the 1st embodiment of the present disclosure. FIG. 3A is a block diagram of a proximity detection keyboard 300 according to the 3rd embodiment of the present disclosure. FIG. 3B is a schematic view of the proximity detection keyboard 300 according to the 3rd embodiment. FIG. 3C is a schematic view of the proximity detection keyboard 300 according to the 3rd embodiment and a user 800. FIG. 3D is a schematic view of a proximity capacitance Cf and a parasitic capacitance Cp of one of electrodes 350 according to the 3rd embodiment. In FIG. 1 and FIG. 3A to FIG. 3D, the proximity detection method 100 is for detecting if at least one part (e.g., a palm, a finger, a wrist, etc.) of a body of the user 800 is proximate to a proximity detection keyboard 300, and the proximity detection keyboard 300 includes a plurality of electrodes 350 and at least one grounding element 370, which is disposed correspondingly to the electrodes 350. The proximity detection method 100 includes an equivalent capacitance detecting step 110 and a proximity event determining step 140. Further, a proximity detection keyboard according to the present disclosure may be a single independent apparatus with buttons, or an assistant apparatus or interface for inputting information to another apparatus (e.g., a desktop computer, a server, etc.). The buttons thereof may be hard buttons (i.e., physical buttons), on-screen buttons, virtual buttons, etc.

The equivalent capacitance detecting step 110 is for detecting an equivalent capacitance Ce (not shown in drawings) of each of the electrodes 350. A proximity capacitance Cf is generated between each of the electrodes 350 and the user 800. A parasitic capacitance Cp is generated between each of the electrodes 350 and the corresponding grounding element 370. The equivalent capacitance Ce of each of the electrodes 350 is defined by the corresponding proximity capacitance Cf and the corresponding parasitic capacitance Cp.

The proximity event determining step 140 is for comparing the equivalent capacitance Ce of at least one of the electrodes 350 and a corresponding capacitance threshold value Cth (not shown in drawings) to determine and recognize if a proximity event is existed. The electrodes 350 are respectively corresponding to the capacitance threshold values Cth being predetermined (i.e., predefined). Accordingly, the capacitive touch/proximity sensing in self capacitance technology is applied in the present disclosure. It allows the electrodes 350 of electrically-conductive metal material to be disposed in the mechanism of the existing standard keyboards or gaming keyboards and to be disposed correspondingly to the grounding element 370. It is advantageous in implementing the proximity detection and gesture detection functions with lower cost and mechanism complexity for the palm, the finger, and the wrist of the user 800 approaching.

In addition, the proximity detection method 100 specifically further includes a proximity response driving step 150. After the proximity event determining step 140, i.e., after comparing the equivalent capacitance Ce of at least one of the electrodes 350 and the corresponding capacitance threshold value Cth (e.g., the proximity event is determined to be existed when the equivalent capacitance Ce of the at least one of the electrodes 350 is greater than the corresponding capacitance threshold value Cth), a response unit 380 of the proximity detection keyboard 300 is driven to correspondingly operate in the proximity response driving step 150.

Furthermore, in the proximity detection method 100, the equivalent capacitance detecting step 110 and the proximity event determining step 140 are performed by a processor 310 of the proximity detection keyboard 300 based on a detection circuit for the electrodes 350. The proximity response driving step 150 is performed by the processor 310 of the proximity detection keyboard 300 outputting a response signal to and drive the response unit 380.

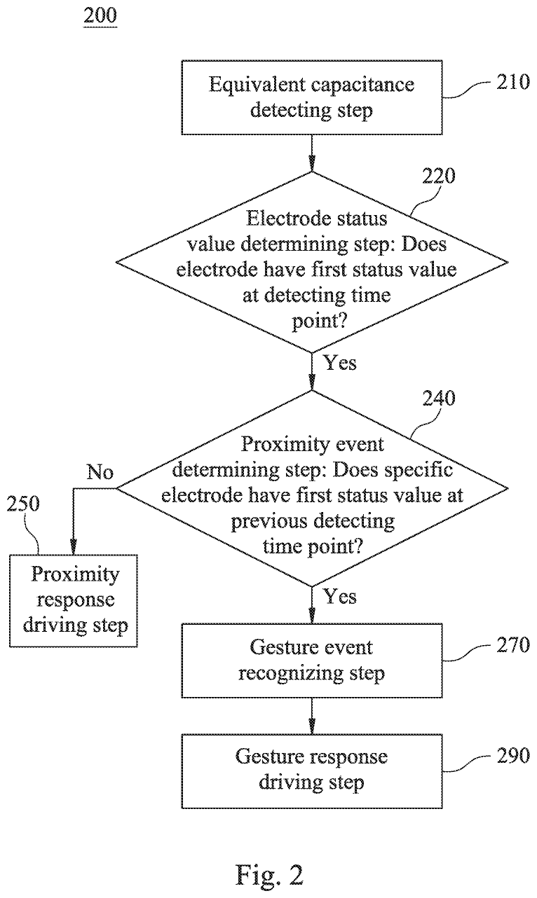

FIG. 2 is a flow chart of a proximity detection method 200 according to the 2nd embodiment of the present disclosure, which is described with an aid of the proximity detection keyboard 300 according to the 3rd embodiment. In FIG. 2 and FIG. 3A to FIG. 3D, the proximity detection method 200 is for detecting if the user 800 is proximate to the proximity detection keyboard 300. The proximity detection method 200 includes an equivalent capacitance detecting step 210 and a proximity event determining step 240.

The equivalent capacitance detecting step 210 is for detecting the equivalent capacitance Ce of each of the electrodes 350. The proximity capacitance Cf is generated between each of the electrodes 350 and the user 800. The parasitic capacitance Cp is generated between each of the electrodes 350 and the corresponding grounding element 370. The equivalent capacitance Ce of each of the electrodes 350 is defined by the corresponding proximity capacitance Cf and the corresponding parasitic capacitance Cp.

The proximity event determining step 240 is for comparing the equivalent capacitance Ce of at least one of the electrodes 350 and the corresponding capacitance threshold value Cth to determine and recognize if a proximity event is existed. The electrodes 350 are respectively corresponding to the capacitance threshold values Cth being predetermined.

In detail, referring to FIG. 3B, each of the electrodes 350 may be in a ring shape (a ring shape with a quadrilateral outline specifically). The proximity detection keyboard 300 may further include a plurality of buttons 340 and a clearance housing portion 303. The clearance housing portion 303 is made of non-electrically-conductive material. Any of the buttons 340 is not disposed on the clearance housing portion 303. The electrodes 350 are correspondingly disposed inside the clearance housing portion 303. Accordingly, it is advantageous in effectively implementing the proximity detection functions of the proximity detection keyboard 300 and reducing the cost in the same time.

Moreover, in FIG. 3B, the clearance housing portion 303 may include a hand pallet set. Each of the electrodes 350 may be physically connected to the clearance housing portion 303 or located on a circuit board of the proximity detection keyboard 300. The at least one grounding element 370 may be physically connected to the clearance housing portion 303 or located on the same or a different circuit board of the proximity detection keyboard 300. Specifically, each of the electrodes 350 is a ring-shaped copper wire and embedded into the clearance housing portion 303 of non-electrically-conductive material (plastic material specifically) in a molding manufacturing process. The grounding element 370 is metal spray on a surface not facing the user 800 of the clearance housing portion 303. Thus, a dielectric distance of the clearance housing portion 303 is between each of the electrodes 350 and the corresponding grounding element 370 to generate the parasitic capacitance Cp. In another embodiment (not shown in drawings), a clearance housing portion includes a frame section around the buttons, and at least one of electrodes may be correspondingly disposed inside the frame section. Each of the electrodes may be in a ring (i.e., hollow) shape, a solid shape, a grid shape etc., and an outline of each of the electrodes may be polygonal, circular, irregular or other shape.

Referring to FIG. 3D, in the equivalent capacitance detecting step 210, the equivalent capacitance Ce of each of the electrodes 350 is the corresponding proximity capacitance Cf added to the corresponding parasitic capacitance Cp. Therefore, the proximity detection could be implemented when the hand (e.g., the palm, the finger, or the wrist) has not been touched the proximity detection keyboard 300 by applying the capacitive touch/proximity sensing in self capacitance technology and the electrodes 350 with the electrically-conductive material of a proper detection sensitivity.

Furthermore, the parasitic capacitance Cp generated between any one of the electrodes 350 and the corresponding grounding element 370 is substantially a constant value. With a hand of the user 800 gradually approaching the any one of the electrodes 350 from a far position, the proximity capacitance Cf generated between the any one of the electrodes 350 and the user 800 is gradually become greater from approximate zero. The proximity capacitance Cf and the parasitic capacitance Cp are equivalently parallel connected. That is, the equivalent capacitance Ce of the any one of the electrodes 350 is the corresponding proximity capacitance Cf added to the corresponding parasitic capacitance Cp. Thus, with the hand of the user 800 gradually approaching the any one of the electrodes 350 from a far position, the equivalent capacitance Ce is gradually become greater from the approximate value of the parasitic capacitance Cp.

Referring to FIG. 2, in the equivalent capacitance detecting step 210, the electrodes 350 are arranged according to a gesture event being predetermined and are respectively corresponding to a plurality of numbers i. The numbers i are continuous integers. The proximity capacitances Cf, the parasitic capacitances Cp and the equivalent capacitances Ce of the electrodes 350 are time dependent and detected at a plurality of detecting time points T, and the detecting time points T have a time interval being predetermined. Therefore, the proximity detection method 200 is beneficial for providing the gesture detection function without extra or excessive circuit elements to be added. Moreover, when the proximity detection keyboard 300 is in a sleep mode, the equivalent capacitance detecting step 210 is regularly and intermittently performed in accordance with a predetermined period.

The proximity detection method 200 further includes an electrode status value determining step 220, which is for determining if at least one of the electrodes 350 has a first status value s1 at one of the detecting time points T. Each of the electrodes 350 has a status value Dᵢ(T) at each of the detecting time points T, and the status value Dᵢ(T) is the first status value s1 (i.e., Dᵢ(T)=s1) or a second status value s2 (i.e., Dᵢ(T)=s2). One of the electrodes 350 is determined to have the first status value s1 when the equivalent capacitance Ce of the one of the electrodes 350 is greater than the corresponding capacitance threshold value Cth. One of the electrodes 350 is determined to have the second status value s2 when the equivalent capacitance Ce of the one of the electrodes 350 is smaller than or equal to the corresponding capacitance threshold value Cth. Therefore, it is advantageous in effectively and instantly determining a proximity situation between the user 800 and each of the electrodes 350. For example, the first status value s1 may be defined to be 1, and the second status value s2 may be defined to be 0, but not limited thereto.

Specifically, when the one of the electrodes 350 has the first status value s1, it is recognized that the user 800 is proximate to the one of the electrodes 350. When the one of the electrodes 350 has the second status value s2, it is recognized that the user 800 is not proximate to the one of the electrodes 350. The capacitance threshold values Cth respectively corresponding to the electrodes 350 may be the same. Each of the capacitance threshold values Cth may be dynamically adapted or adjusted in accordance with different environmental conditions, e.g. temperature, humidity, power supply background noise level, etc. Furthermore, any of the proximity capacitances Cf, the parasitic capacitances Cp, the equivalent capacitances Ce and the capacitance threshold values Cth may be correspondingly converted from an electrical parameter, e.g., a voltage, a current, etc., to determine the status values Dᵢ(T) of the electrodes 350, but not limited thereto.

In detail, the proximity event determining step 240 is further for selecting one of the electrodes 350 corresponding to a maximum number imax among the at least one of the electrodes 350 when the at least one of the electrodes 350 has the first status value s1 at the one of the detecting time points T. The one of the electrodes 350 corresponding to the maximum number imax has the status value Dᵢₘₐₓ(T)=s1. The maximum number imax is a maximum among the at least one number corresponding to the at least one of the electrodes 350 having the first status value s1 at the one of the detecting time points T. The proximity event determining step 240 is further for determining if one of the electrodes 350 corresponding to a previous number imax−1 or a next number imax+1 with respect to the maximum number imax has the first status value s1 at a previous detecting time point T−1 (i.e., a previous one with respect to the one of the detecting time points T). That is, determining if at least one of Dᵢₘₐₓ₋₁(T−1)=s1 and Dᵢₘₐₓ₊₁(T−1)=s1 is existed. In addition, the specific electrode in the proximity event determining step 240 in FIG. 2 is the one of the electrodes 350 corresponding to the previous number imax−1 or the one of the electrodes 350 corresponding to the next number imax+1. Accordingly, the proximity detection method 200 is beneficial to further determine a proximity event merely or a gesture event among various kinds of proximity events after determining the proximity event.

The proximity detection method 200 further includes a proximity response driving step 250 for determining and recognizing as the proximity event and driving the response unit 380 of the proximity detection keyboard 300 to correspondingly operate when the two of the electrodes 350 respectively corresponding to the previous number imax−1 and the next number imax+1 with respect to the maximum number imax do not have the first status values s1 at the previous detecting time point T−1. It is noted that in the electrode status value determining step 220 being previously performed, the at least one of the electrodes 350 having the first status value s1 at one of the detecting time points T is determined. The response unit 380 includes at least one of an output port (of wiredly or wirelessly transmitting), a lighting element, a sound element and a vibration element. Accordingly, it is advantageous in further reporting to a main chip (or the processor 310) of the proximity detection keyboard 300 with a successful detection result for developing a particular response function, so that a better experience resulted from the smart functions of the proximity detection keyboard 300 is allowed to be provided to the users. For example, recognizing as the proximity event in the proximity response driving step 250 may trigger the response unit 380 to perform a sound feedback, a vibration feedback, a lighting feedback of statically or dynamically illuminating the display backlight, a feedback of waking up a monitor outside the proximity detection keyboard 300 via the output port, etc.

The proximity detection method 200 further includes a gesture event recognizing step 270 for recognizing as the gesture event according to a time sequence Dts of the electrode status values. When the one of the electrodes 350 corresponding to the previous number imax−1 with respect to the maximum number imax has the first status value s1 at the previous detecting time point T−1, the time sequence Dts of the electrode status values are the status values Dᵢ(T) of the electrodes 350 corresponding to plural previous continuous numbers imax−1, imax−2 . . . with respect to the maximum number imax respectively at previous continuous detecting time points T−1, T−2 . . . (i.e., previous continuous ones with respect to the one of the detecting time points T). When the one of the electrodes 350 corresponding to the next number imax+1 with respect to the maximum number imax has the first status value s1 at the previous detecting time point T−1, the time sequence Dts of the electrode status values are the status values Dᵢ(T) of the electrodes 350 corresponding to plural next continuous numbers imax+1, imax+2 . . . with respect to the maximum number imax respectively at previous continuous detecting time points T−1, T−2 . . . Therefore, the gesture detection function of the proximity detection method 200 could be implemented by the arrangement relationships and configurations among the electrodes 350.

The proximity detection method 200 further includes a gesture response driving step 290 for correspondingly driving the response unit 380 of the proximity detection keyboard 300 to correspondingly operate according to the gesture event being recognized. The response unit 380 includes at least one of the output port, the lighting element, the sound element and the vibration element. Therefore, it is advantageous in providing the users 800 with new value-added experiences and creating an extra added value of the human-machine interaction of the standard keyboards or the gaming keyboards. For example, driving the response unit 380 in the gesture response driving step 290 may be triggering the response unit 380 to transmit signals by the output port for turning the pages in a reading software, controlling the motions in a game software, fine-tuning the volume or screen brightness in an operating system software, etc. in a desktop computer, which is coupled to the proximity detection keyboard 300.

Regarding the proximity detection method 200 according to the present disclosure, for example, in the proximity event determining step 240, the electrodes 350 of the proximity detection keyboard 300 are respectively corresponding to the numbers i=1 to i=4 in order from left to right in FIG. 3B and FIG. 3C. When two of the electrodes 350 with the numbers i=2 and i=3 have the first status value s1 at one of the detecting time points T, i.e., D₂(T)=s1 and D₃(T)=s1, one of the two of the electrodes 350 corresponding to a maximum number imax among the two of the electrodes 350, i.e., imax=3, is selected. Then, it is determined if one of the electrodes 350 corresponding to a previous number imax−1=2 or a next number imax+1=4 with respect to the maximum number imax=3 having the first status value s1 at a previous detecting time point T−1, that is, it is determined if at least one of D₂(T−1)=s1 and D₄(T−1)=s1 is existed. In the proximity response driving step 250, when two of the electrodes 350 respectively corresponding to the previous number imax−1=2 and the next number imax+1=4 with respect to the maximum number imax=3 do not have the first status values s1 at the previous detecting time point T−1, i.e., D₂(T−1)=s2 and D₄(T−1)=s2, it is determined and recognized as a proximity event merely (instead of a gesture event) to drive the response unit 380 of the proximity detection keyboard 300. In the gesture event recognizing step 270, when the one of the electrodes 350 corresponding to the previous number imax−1=2 with respect to the maximum number imax=3 has the first status value s1 at the previous detecting time point T−1, a time sequence Dts of the electrode status values are the status values D₂(T−1)=S1, (T−2)=S1 of the electrodes 350 corresponding to plural previous continuous numbers imax−1=2, imax−2=1 with respect to the maximum number imax=3 respectively at previous continuous detecting time points T−1, T−2. Then, it is recognized as the gesture event being predetermined, e.g., a gesture of turning the pages, according to the time sequence Dts of the electrode status values, i.e., the time sequence Dts being arranged with D₂(T−1)=S1, D₁(T−2)=S1. In the gesture response driving step 290, the output port served as the response unit 380 of the proximity detection keyboard 300 is driven according to the gesture event to cause to turn the page in the reading software in a desktop computer, which is coupled to the proximity detection keyboard 300.

Furthermore, when all the electrodes 350 do not have the first status value s1 (i.e., do have the second status value s2) at one of the detecting time points T in the electrode status value determining step 220, or after at least one step of the proximity response driving step 250, the gesture event recognizing step 270 and the gesture response driving step 290 is performed, the equivalent capacitance detecting step 210 may be repeated.

Moreover, in the proximity detection method 200, the equivalent capacitance detecting step 210, the electrode status value determining step 220, the proximity event determining step 240 and the gesture event recognizing step 270 are performed by the processor 310 of the proximity detection keyboard 300 based on the detection circuit for the electrodes 350. The proximity response driving step 250 and the gesture response driving step 290 are performed by the processor 310 of the proximity detection keyboard 300 outputting a response signal to and drive the response unit 380.

In FIG. 3B, a quantity of the electrodes 350 may be between 2 and 50 (including 2 and 50, applied in the following). Accordingly, it is advantageous in reducing the development cost and time of the proximity detection method 200.

An area ae of each of the electrodes 350 may be between 1 cm² and 900 cm². The area ae of each of the electrodes 350 indicates an area of the electrically-conductive material. Accordingly, it is advantageous in designing the actual mechanism size of the proximity detection keyboard 300 and the detection circuit.

The corresponding capacitance threshold value Cth of each of the electrodes 350 may be between 1 pF and 1000 pF. Therefore, it is beneficial to reduce the complexity of the detection circuit and be properly cooperated with the quantity of the electrodes 350 and the area ae of each of the electrodes 350.

A distance de from the user 800 to the at least one of the electrodes 350 recognized as the proximity event and the gesture event may be between 0.5 cm and 30 cm. Therefore, it is properly applicable to the proximity and gesture detection functions. In addition, a delay time between the user 800 entering the distance de (i.e., 0.5 cm to 30 cm distant from the at least one of the electrodes 350) and the response unit 380 correspondingly operating may be smaller than 2.0 sec.

Regarding the proximity detection keyboard 300 of the 3rd embodiment according to the present disclosure, it could be described with an aid of the proximity detection method 100 of the 1st embodiment or the proximity detection method 200 of the 2nd embodiment, and the proximity detection keyboard 300 is described with the aid of the proximity detection method 200 of the 2nd embodiment in the following. The proximity detection keyboard 300 is configured to detect if the user 800 is proximate to the proximity detection keyboard 300. The proximity detection keyboard 300 includes the buttons 340, the clearance housing portion 303, the electrodes 350, the at least one grounding element 370, the processer 310 and a nonvolatile memory 320.

The clearance housing portion 303 is made of non-electrically-conductive material. Any of the buttons 340 is not disposed on the clearance housing portion 303. The electrodes 350 are correspondingly disposed inside the clearance housing portion 303. The at least one grounding element 370 is disposed correspondingly to the electrodes 350. The processer 310 is coupled to the buttons 340, the electrodes 350 and the at least one grounding element 370. The nonvolatile memory 320 is coupled to the processer 310 and configured to provide a proximity detection module 322. It will be understood that each circuit element may be directly coupled to the at least one grounding element 370, or coupled to the at least one grounding element 370 via a grounding circuit. The processer 310 is configured to determine if the proximity event is existed according to the proximity detection module 322, and the proximity detection module 322 is for performing the equivalent capacitance detecting step 210 and the proximity event determining step 240. Accordingly, the proximity detection function of the proximity detection keyboard 300 could be implemented. Specifically, the proximity detection module 322 may be firmware programming codes or software programming codes stored in the nonvolatile memory 320. The processer 310 and the nonvolatile memory 320 may be respectively two parts of the main chip (or microcontroller) of the proximity detection keyboard 300, or the proximity detection module 322 may be performed by the cooperation of processers 310 and nonvolatile memories 320 of at least two microcontrollers (e.g., a main chip and a proximity detection control chip), but not limited thereto.

In detail, the clearance housing portion 303 includes the hand pallet set. Each of the electrodes 350 is physically connected to the clearance housing portion 303 or located on a circuit board of the proximity detection keyboard 300. The at least one grounding element 370 is physically connected to the clearance housing portion 303 or located on the same or a different circuit board of the proximity detection keyboard 300. Accordingly, it is advantageous in reducing the circuit and mechanism design complexity and ensuring the effective proximity detection.

The proximity detection keyboard 300 may further include the response unit 380 coupled to the processer 310. The processer 310 is configured to output a response signal to the response unit 380 according to the proximity detection module 322 to drive the response unit 380 to correspondingly operate. Therefore, it is advantageous in providing the users 800 with new value-added experiences.

The contents related to the proximity detection method 100 according to the 1st embodiment or the proximity detection method 200 according to the 2nd embodiment may be referred for the other details of the proximity detection module 322 of the proximity detection keyboard 300 according to the 3rd embodiment, which are thereby not described herein.

Although the present disclosure has been described in considerable detail with reference to certain embodiments thereof, other embodiments are possible. Therefore, the spirit and scope of the appended claims should not be limited to the description of the embodiments contained herein. It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A proximity detection method, for detecting if a user is proximate to a proximity detection keyboard, the proximity detection keyboard comprising a plurality of electrodes and at least one grounding element, which is disposed correspondingly to the electrodes, the proximity detection method comprising:
an equivalent capacitance detecting step for detecting an equivalent capacitance of each of the electrodes, wherein a proximity capacitance is generated between each of the electrodes and the user, a parasitic capacitance is generated between each of the electrodes and the corresponding grounding element, and the equivalent capacitance of each of the electrodes is defined by the corresponding proximity capacitance and the corresponding parasitic capacitance; and
a proximity event determining step for comparing the equivalent capacitance of at least one of the electrodes and a corresponding capacitance threshold value to determine if a proximity event is existed, wherein the electrodes are respectively corresponding to the capacitance threshold values being predetermined.

2. The proximity detection method of claim 1, wherein each of the electrodes is in a ring shape, the proximity detection keyboard further comprises a plurality of buttons and a clearance housing portion, the clearance housing portion is made of non-electrically-conductive material, any of the buttons is not disposed on the clearance housing portion, and the electrodes are correspondingly disposed inside the clearance housing portion;
wherein in the equivalent capacitance detecting step, the equivalent capacitance of each of the electrodes is the corresponding proximity capacitance added to the corresponding parasitic capacitance.

3. The proximity detection method of claim 2, wherein in the equivalent capacitance detecting step, the electrodes are arranged according to a gesture event being predetermined and are respectively corresponding to a plurality of numbers, the numbers are continuous integers, the proximity capacitances, the parasitic capacitances and the equivalent capacitances of the electrodes are time dependent and detected at a plurality of detecting time points, and the detecting time points have a time interval being predetermined.

4. The proximity detection method of claim 3, further comprising:
an electrode status value determining step for determining if at least one of the electrodes has a first status value at one of the detecting time points, wherein each of the electrodes has a status value at each of the detecting time points, the status value is the first status value or a second status value, one of the electrodes is determined to have the first status value when the equivalent capacitance of the one of the electrodes is greater than the corresponding capacitance threshold value, and one of the electrodes is determined to have the second status value when the equivalent capacitance of the one of the electrodes is smaller than or equal to the corresponding capacitance threshold value;
wherein the proximity event determining step is further for selecting one of the electrodes corresponding to a maximum number among the at least one of the electrodes when the at least one of the electrodes has the first status value at the one of the detecting time points, and further for determining if one of the electrodes corresponding to a previous number or a next number with respect to the maximum number has the first status value at a previous one with respect to the one of the detecting time points, and the maximum number is a maximum among the at least one number corresponding to the at least one of the electrodes having the first status value at the one of the detecting time points.

5. The proximity detection method of claim 4, further comprising:
a proximity response driving step for determining as the proximity event and driving a response unit of the proximity detection keyboard when the two of the electrodes respectively corresponding to the previous number and the next number with respect to the maximum number do not have the first status values at the previous one of the detecting time points;
wherein the response unit comprises at least one of an output port, a lighting element, a sound element and a vibration element.

6. The proximity detection method of claim 4, further comprising:
a gesture event recognizing step for recognizing as the gesture event according to a time sequence of the electrode status values;
wherein when the one of the electrodes corresponding to the previous number with respect to the maximum number has the first status value at the previous one of the detecting time points, the time sequence of the electrode status values are the status values of the electrodes corresponding to plural previous continuous numbers with respect to the maximum number respectively at previous continuous ones of the detecting time points;
wherein when the one of the electrodes corresponding to the next number with respect to the maximum number has the first status value at the previous one of the detecting time points, the time sequence of the electrode status values are the status values of the electrodes corresponding to plural next continuous numbers with respect to the maximum number respectively at previous continuous ones of the detecting time points.

7. The proximity detection method of claim 6, further comprising:
a gesture response driving step for driving a response unit of the proximity detection keyboard according to the gesture event;
wherein the response unit comprises at least one of an output port, a lighting element, a sound element and a vibration element.

8. The proximity detection method of claim 1, wherein a quantity of the electrodes is between 2 and 50, and an area of each of the electrodes is between 1 cm² and 900 cm².

9. The proximity detection method of claim 1, wherein the corresponding capacitance threshold value of each of the electrodes is between 1 pF and 1000 pF, and a distance from the user to the at least one of the electrodes of the proximity event is between 0.5 cm and 30 cm.

10. A proximity detection keyboard, comprising:
a plurality of buttons;
a clearance housing portion made of non-electrically-conductive material, wherein any of the buttons is not disposed on the clearance housing portion;
a plurality of electrodes correspondingly disposed inside the clearance housing portion;
at least one grounding element disposed correspondingly to the electrodes;
a processer coupled to the buttons, the electrodes and the at least one grounding element; and
a nonvolatile memory coupled to the processer and configured to provide a proximity detection module;
wherein the processer is configured to determine if a proximity event is existed according to the proximity detection module, and the proximity detection module is for performing an equivalent capacitance detecting step and a proximity event determining step;
wherein the equivalent capacitance detecting step is detecting an equivalent capacitance of each of the electrodes, a proximity capacitance is generated between each of the electrodes and a user, a parasitic capacitance is generated between each of the electrodes and the corresponding grounding element, and the equivalent capacitance of each of the electrodes is defined by the corresponding proximity capacitance and the corresponding parasitic capacitance;
wherein the proximity event determining step is comparing the equivalent capacitance of at least one of the electrodes and a corresponding capacitance threshold value to determine if the proximity event is existed, and the electrodes are respectively corresponding to the capacitance threshold values being predetermined.

11. The proximity detection keyboard of claim 10, wherein each of the electrodes is in a ring shape, the clearance housing portion comprises a hand pallet set, each of the electrodes is connected to the clearance housing portion or located on a circuit board of the proximity detection keyboard, and the at least one grounding element is connected to the clearance housing portion or located on a circuit board of the proximity detection keyboard;
wherein in the equivalent capacitance detecting step provided by the proximity detection module, the equivalent capacitance of each of the electrodes is the corresponding proximity capacitance added to the corresponding parasitic capacitance.

12. The proximity detection keyboard of claim 11, wherein in the equivalent capacitance detecting step provided by the proximity detection module, the electrodes are arranged according to a gesture event being predetermined and are respectively corresponding to a plurality of numbers, the numbers are continuous integers, the proximity capacitances, the parasitic capacitances and the equivalent capacitances of the electrodes are time dependent and detected at a plurality of detecting time points, and the detecting time points have a time interval being predetermined.

13. The proximity detection keyboard of claim 12, wherein the proximity detection module is further for performing an electrode status value determining step, the electrode status value determining step is determining if at least one of the electrodes has a first status value at one of the detecting time points, each of the electrodes has a status value at each of the detecting time points, the status value is the first status value or a second status value, one of the electrodes is determined to have the first status value when the equivalent capacitance of the one of the electrodes is greater than the corresponding capacitance threshold value, and one of the electrodes is determined to have the second status value when the equivalent capacitance of the one of the electrodes is smaller than or equal to the corresponding capacitance threshold value;
wherein the proximity event determining step provided by the proximity detection module is further selecting one of the electrodes corresponding to a maximum number among the at least one of the electrodes when the at least one of the electrodes has the first status value at the one of the detecting time points, and further determining if one of the electrodes corresponding to a previous number or a next number with respect to the maximum number has the first status value at a previous one with respect to the one of the detecting time points, and the maximum number is a maximum among the at least one number corresponding to the at least one of the electrodes having the first status value at the one of the detecting time points.

14. The proximity detection keyboard of claim 13, further comprising:
a response unit coupled to the processer, wherein the processer is configured to output a response signal to the response unit according to the proximity detection module to drive the response unit to correspondingly operate, and the response unit comprises at least one of an output port, a lighting element, a sound element and a vibration element;
wherein the proximity detection module is further for performing a proximity response driving step, and the proximity response driving step is determining as the proximity event and driving the response unit of the proximity detection keyboard when the two of the electrodes respectively corresponding to the previous number and the next number with respect to the maximum number do not have the first status values at the previous one of the detecting time points.

15. The proximity detection keyboard of claim 13, wherein the proximity detection module is further for performing a gesture event recognizing step, and the gesture event recognizing step is recognizing as the gesture event according to a time sequence of the electrode status values;
wherein when the one of the electrodes corresponding to the previous number with respect to the maximum number has the first status value at the previous one of the detecting time points, the time sequence of the electrode status values are the status values of the electrodes corresponding to plural previous continuous numbers with respect to the maximum number respectively at previous continuous ones of the detecting time points;
wherein when the one of the electrodes corresponding to the next number with respect to the maximum number has the first status value at the previous one of the detecting time points, the time sequence of the electrode status values are the status values of the electrodes corresponding to plural next continuous numbers with respect to the maximum number respectively at previous continuous ones of the detecting time points.

16. The proximity detection keyboard of claim 15, further comprising:
a response unit coupled to the processer, wherein the processer is configured to output a response signal to the response unit according to the proximity detection module to drive the response unit to correspondingly operate, and the response unit comprises at least one of an output port, a lighting element, a sound element and a vibration element;
wherein the proximity detection module is further for performing a gesture response driving step, and the gesture response driving step is driving the response unit of the proximity detection keyboard according to the gesture event.

17. The proximity detection keyboard of claim 10, wherein a quantity of the electrodes is between 2 and 50, and an area of each of the electrodes is between 1 cm² and 900 cm².

18. The proximity detection keyboard of claim 10, wherein the corresponding capacitance threshold value of each of the electrodes is between 1 pF and 1000 pF, and a distance from the user to the at least one of the electrodes of the proximity event is between 0.5 cm and 30 cm.
